(19) United States
(12) Patent Application Publication
(10) Pub. No.: US 2025/0309220 A1
(43) Pub. Date: Oct. 2, 2025

(54) HALF-BRIDGE TOPOLOGY INTEGRATION METHOD FOR CO-PACKAGING GALLIUM NITRIDE POWER DEVICE AND CHIP

(71) Applicant: Dongke Semiconductor (Anhui) CO., LTD, Ma'anshan, Anhui (CN)

(72) Inventors: Shaofeng Zhao, Ma’anshan, Anhui (CN); Zhaohui Cheng, Ma’anshan, Anhui (CN); Jingwei Sun, Ma’anshan, Anhui (CN)

(21) Appl. No.: 18/864,478

(22) PCT Filed: Jun. 28, 2022
(86) PCT No.: PCT/CN2022/101741

§ 371 Date: Nov. 8, 2024

(30) Foreign Application Priority Data
May 18, 2022 (CN) 202210543201

(51) Int. Cl. H01L 25/00; H01L 23/495

(52) U.S. Cl. CPC H01L 25/50; H01L 23/49541; H01L 23/49575

(57) ABSTRACT

A half-bridge topology integration method for co-packaging a gallium nitride power device and a includes packaging a driving control module, a first power transistor and a second power transistor. The driving control module comprises a logic control circuit and a half-bridge driving circuit. The half-bridge driving circuit comprises a starting circuit, a high-side driver and a low-side driver. The logic control circuit is connected to the half-bridge driving circuit. The first power transistor and the second power transistor are connected in series, and the driving output of the half-bridge driving circuit is separately connected to driving ends of the first power transistor and of the second power transistor. The first power transistor and the second power transistor are alternately turned on and turned off. The logic control circuit, the half-bridge driving circuit, the first power transistor and the second power transistor are packaged in one chip.

### CROSS-REFERENCE TO RELATED APPLICATIONS

This application is a national phase entry under 35 U.S.C. § 371 of International Patent Application PCT/CN2022/101741, filed Jun. 28, 2022, designating the United States of America and published as International Patent Publication WO 2023/221248 A1 on Nov. 23, 2023, which claims the benefit under Article 8 of the Patent Cooperation Treaty of Chinese Patent Application Serial No. 202210543201.0, entitled “Half-bridge topology integration method for co-packaging a gallium nitride power device and chip,” and filed before the Patent Office of the People's Republic of China on May 18, 2022.

### TECHNICAL FIELD

The present disclosure relates to the technical field of integrated circuits, and particularly relates to a half-bridge topology integration method for co-packaging a gallium nitride power device and a chip.

### BACKGROUND

A half-bridge driving circuit is widely applied to an electronic ballast, a pulse width modulation (PWM) motor driver and an inverter circuit, and includes a discrete component drive, a pulse triggering transformer drive and a dedicated integrated chip drive. The discrete component drive features low price. However, due to the low integration level, the application of the discrete component drive is limited. The pulse triggering transformer drive has the advantage of convenient implementation. However, due to manufacturing errors, distortion of two driving signals is easily caused, and the transformer is large in size and emits heat severely. The dedicated integrated chip has features of small size, high reliability, high efficiency and the like.

Half-bridge topology of the power switching device is a common structure in a medium-high power switching power supply, which can reduce the voltage stress of a primary side power switching device of the transformer. To reduce the switching loss, a soft switching zero voltage switching (ZVS) is usually used in half-bridge topology such as active clamping, LLC resonance, so that the switching frequency can be increased, and the product size can be reduced.

Because a third-generation semiconductor material gallium nitride (GaN) have features of a high switching frequency, a large band-gap width and low on resistance and is able to naturally match the soft switching ZVS control technology of half-bridge topology due to a high frequency characteristic of the GaN, the switching frequency can be increased greatly without increasing the switching loss, so that the power density is further improved. The GaN fits the development trend of small size, light weight and high efficiency of the switching power supply in the extreme.

A threshold voltage Vth and a gate-source withstand voltage of a high-voltage enhanced GaN power device are lower than those of a silicon (Si)-based power device, and the high-voltage enhanced GaN power device has a high requirement for the precision of a gate-source driving voltage. In the prior art, a drive and the GaN power device are separated and are connected through printed circuit board (PCB) wiring externally. As shown in FIG. 1, K1 and K2 are discrete high-side and low-side GaN power devices separately. The driver is also an independent chip. L1-L10 are bonding parasitic inductors during packaging. L11-L14 are wiring parasitic inductors of the PCB. The parasitic inductor of a driving loop of the high-side power device K2 includes L1, L11, L5, L6, L12 and L2 connected in series. An inductor of a driving loop of the low-side power device includes L3, L13, L8, L10, L14 and L4 connected in series. It can be known from FIG. 1 that the parasitic inductance of the low-side and high-side driving loops is high. The gate-source voltage of K1 and K2, i.e., a driving voltage VGS, will generate a ringing effect. As shown in FIG. 2, overshoot and undershoot of the VGS are quite apparent. Thanks to the low gate-source withstand voltage of the GaN, if a ringing spike voltage VGSmax of the drive exceeds a gate-source breakdown voltage of the GaN, the device will be damaged.

### BRIEF SUMMARY

An object of the present disclosure is to provide a half-bridge topology integration method for co-packaging a gallium nitride power device and a chip. A high-voltage starting circuit of half-bridge topology, a logic control circuit, a dedicated driving circuit for the GaN power device and the GaN power device are packaged and integrated in a same chip and are arranged reasonably, so that parasitic parameters in a driving loop are reduced. The number of peripheral devices of a power supply chip is greatly reduced while heat dissipation of the power device is guaranteed, so that the power density is improved, the device is easy to debug, and the application cost is reduced.

Therefore, in a first aspect, embodiments of the present disclosure provide a half-bridge topology integration method for co-packaging a gallium nitride power device, including:
packaging a driving control module, a first gallium nitride power transistor and a second gallium nitride power transistor in a chip to form a co-packaged gallium nitride half-bridge topology integrated chip, where the driving control module comprises a logic control circuit and a half-bridge driving circuit; the half-bridge driving circuit comprises a high-voltage starting circuit, a high-side driver and a low-side driver;
isolating, a first base island region and a second base island region with an insulating layer in the chip; arranging the driving control module and the second gallium nitride power transistor in the first base island region, and arranging the first gallium nitride power transistor in the second base island region; and
connecting the logic control circuit to the half-bridge driving circuit, connecting the first gallium nitride power transistor and the second gallium nitride power transistor in series, and separately connecting a driving output of the half-bridge driving circuit to driving ends of the first gallium nitride power transistor and the second gallium nitride power transistor, where the half-bridge driving circuit drives, according to a control signal output by the logic control circuit, the first gallium nitride power transistor and the second gallium nitride power transistor to be alternately turned on and turned off.

Preferably, a power quad dual flat pin-free packaging structure that adopts PDNF is specifically used for packaging, and the method further includes:
arranging pins connected to a high-voltage signal in the chip on one side of the PDNF package, and arranging pins connected to a low-voltage signal in the chip on the other side of the PDNF package;
where the pins connected to the high-voltage signal includes pin V+, which is a high-voltage input positive, VCCH pin as a power supply input of the high-side driver, pin HV as an input of a high-voltage starting circuit and a half-bridge output pin HB; the pins connected to the low-voltage signal includes pin VCC, which is a power supply input of the chip and a plurality of input/output I/O; and
the pins of the chip further comprise a high-voltage input negative pin V−, where the high-voltage input negative pin V− is arranged on the other side of the PDNF package or a third side.

Further preferably, the pin VCC as the power supply input end of the chip is separately connected to the logic control circuit, the high-voltage starting circuit, the high-side driver and the low-side driver;
the pin HV as the input end of the high-voltage starting circuit is connected to the high-voltage starting circuit, and an output end of the high-voltage starting circuit is separately connected to the logic control circuit, the high-side driver and the low-side driver;
the logic control circuit is connected to the plurality of input/output I/O ends;
a first control signal output end of the logic control circuit is connected to a driving signal input end of the high-side driver, and a signal output end of the high-side driver is connected to a gate of the first gallium nitride power transistor;
a second control signal output end of the logic control circuit is connected to a driving signal input end of the low-side driver, and a signal output end of the low-side driver is connected to a gate of the second gallium nitride power transistor; and
the high-voltage input positive pin V+ is connected to a drain of the first gallium nitride power transistor, and a source of the second gallium nitride power transistor is connected to the high-voltage input negative pin V−; and a source of the first gallium nitride power transistor is connected to a drain of the second gallium nitride power transistor and is connected to the half-bridge output pin HB.

Further preferably, the logic control circuit, according to input signals of the plurality of input/output I/O, outputs a first control signal that adopts PWMH and a second control signal that adopts PWML;
the high-side driver, according to the first control signal, which is PWMH, outputs a first gate driving signal of the first gallium nitride power transistor; the low-side driver, according to the second control signal, which is PWML, outputs a second gate driving signal of the second gallium nitride power transistor; and the first gallium nitride power transistor and the second gallium nitride power transistor, driven by the first gate driving signal and the second gate driving signal, are alternately turned on and turned off; and
where the first control signal and the second control signal are complementary pulse width modulation signals.

Further preferably, the method further includes:
further separately connecting earthing terminals of the logic control circuit, the high-voltage starting circuit, the high-side driver and the low-side driver to the high-voltage input negative pin V−; and
connecting a feedback end of the high-side driver to the half-bridge output pin HB.

Preferably, the pins of the chip are isolated by the insulating layer.

Preferably, copper sheets are exposed to a back surface of the chip corresponding to the first base island region and the second base island region.

Preferably, the package is specifically a DNF8*8 package.

In a second aspect, the embodiments of the present disclosure further provide a half-bridge topology integrated chip obtained by the half-bridge topology integration method for co-packaging a gallium nitride power device according to the first aspect.

According to the half-bridge topology integration method for co-packaging a gallium nitride power device provided in the embodiments of the present disclosure, aiming at the characteristics of the GaN power device, the high-voltage starting circuit of half-bridge topology, the logic control circuit, the dedicated driving circuit for the GaN power device and the GaN power device are packaged and integrated in the same chip and are isolated with the insulating layer, which separates the base island regions. The pin of the low-voltage signal is arranged on one side and the pin of the high-voltage signal is arranged on the other side with a packaging architecture, so that physical spaces of the high-voltage and low-voltage signals are isolated. The copper sheets are exposed to the back surfaces of the base island regions, so that the back surface can be directly welded to the PCB when the chip is applied, which guarantees the heat dissipation performance of the chip. Compared with the prior art, the parasitic parameters in the driving loop are reduced. The number of peripheral devices of a power supply chip is greatly reduced while heat dissipation of the power device is guaranteed, so that the power density is improved, the device is easy to debug, and the application cost is reduced.

### BRIEF DESCRIPTION OF THE DRAWINGS

FIG. 1 is a schematic diagram of distribution of parasitic inductors of separated GaN power device and driving chip provided in the prior art;

FIG. 2 is a schematic diagram of a wave form of a Gate driving voltage VGS of the GaN power device,

FIG. 3 is a schematic diagram of a half-bridge topology integrated chip for co-packaging a gallium nitride power device provided by the present disclosure;

FIG. 4 is a picture of a real product of a chip prepared by a half-bridge topology integration method provided in an embodiment of the present disclosure;

FIG. 5 is a schematic diagram of a specific implementation of a pin of the chip provided by the present disclosure;

FIG. 6 is a schematic diagram of a half-bridge driving signal provided by the present disclosure;

FIG. 7 is a schematic diagram of distribution of parasitic inductors in the half-bridge topology integrated chip for co-packaging a gallium nitride power device provided by the present disclosure;

FIG. 8 is a comparison diagram of a wave form in the present disclosure and the wave form of the Gate driving voltage VGS of the gate in FIG. 2;

FIG. 9 shows a half-bridge driving chip structure applied to an LLC serial resonant architecture of a specific implementation of the half-bridge topology integration method provided by the present disclosure; and

FIG. 10 shows a half-bridge driving chip structure applied to an active clamping flyback architecture of a specific implementation of the half-bridge topology integration method provided by the present disclosure.

### DETAILED DESCRIPTION

The technical solution of the present disclosure will be further described in detail with reference to the accompanying drawings and the embodiments.

Embodiments of the present disclosure provide a half-bridge topology integration method for co-packaging a gallium nitride power device, including:
packaging a driving control module 1, a first gallium nitride power transistor K1 and a second gallium nitride power transistor K2 in a chip to form a co-packaged gallium nitride half-bridge topology integrated chip, where the package is specifically of a power quad dual flat pin-free packaging structure, which is PDNF.

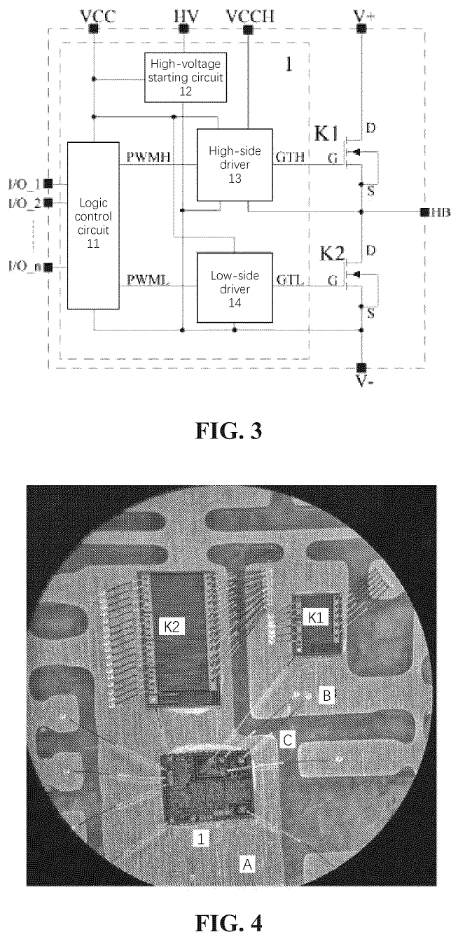

The structure of the chip is shown in FIG. 3. Description will be made below in combination with FIG. 3.

The driving control module 1 includes:
a logic control circuit 11 and a half-bridge driving circuit; the half-bridge driving circuit includes a high-voltage starting circuit 12, a high-side driver 13 and a low-side driver 14; and
a pin of the chip includes a high-voltage input positive pin V+, a high-voltage input negative pin V−, VCCH pin as a power supply input of the high-side driver, pin HV as an input of a high-voltage starting circuit, a power supply input pin VCC of the chip, a plurality of input/output I/O ends and a half-bridge output pin HB.

To achieve isolation of the high-voltage and low-voltage signals in physical space, the pin of the low-voltage signal is arranged on one side, and the pin of the high-voltage signal is arranged on the other side in the packaging structure. In addition, in terms of physical implementation of the chip, a first base island region and a second base island region are isolated by an insulating layer, the driving control module 1 and the second gallium nitride power transistor K2 are arranged in the first base island region, and the first gallium nitride power transistor K1 is arranged in the second base island region, so that a bonding optimizing purpose is achieved while achieving isolation. In addition, the pins of the chip are also isolated by the insulating layer in physical implementation.

A real product of the chip prepared by the half-bridge topology integration method provided in an embodiment of the present disclosure is shown in FIG. 4. It can be seen that the driving control module 1 and the second gallium nitride power transistor K2 are arranged in the first base island region A, while the first gallium nitride power transistor K1 is arranged in the second base island region B, and the first and second gallium nitride power transistors are isolated with the insulating layer C.

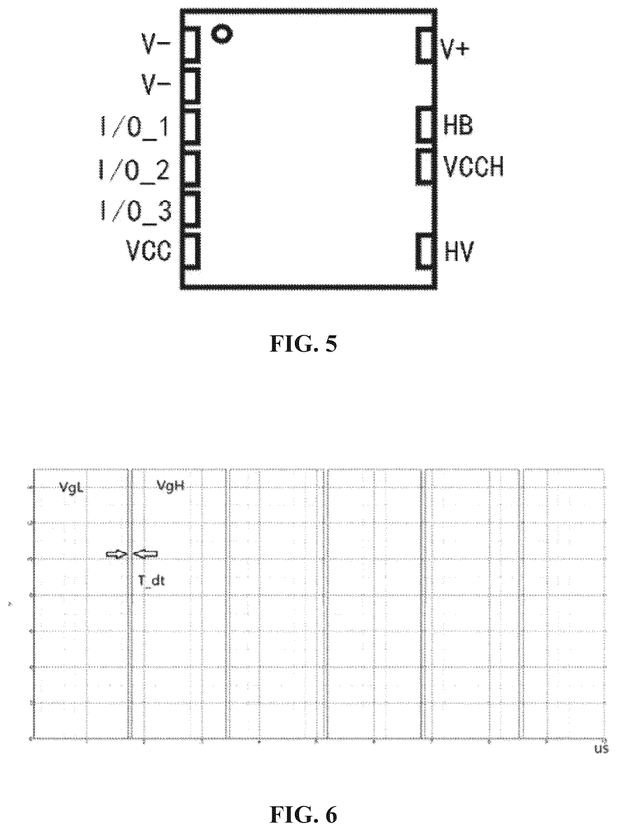

In the chip, the pin connected to the high-voltage signal includes a high-voltage input positive pin V+, a power supply input pin VCCH of the high-side driver, an input pin HV of a high-voltage starting circuit and a half-bridge output pin HB; the pins connected to the low-voltage signal includes pin VCC, which is a power supply input of the chip and a plurality of input/output I/O; and the pins of the chip further include a high-voltage input negative pin V−, where the high-voltage input negative pin V− is arranged on the other side of the PDNF package or a third side. In a specific implementation, the pins are arranged as shown in FIG. 5.

Preferably, the package is a DNF8*8 package; and in terms of pin arrangement, the pin connected to the high-voltages signal in the chip is arranged on one side of the DNF8*8 package, and the pin connected to the low-voltages signal in the chip is arranged on the other side of the DNF8*8 package.

In the chip, by following the above structure, the logic control circuit 11 is connected to the half-bridge driving circuit, the first gallium nitride power transistor K1 and the second gallium nitride power transistor K2 are connected in series, and a driving output of the half-bridge driving circuit is separately connected to driving ends of the first gallium nitride power transistor K1 and the second gallium nitride power transistor K2, so that according to a control signal output by the logic control circuit, the half-bridge driving circuit drives the first gallium nitride power transistor and the second gallium nitride power transistor to be alternately turned on and turned off.

Specifically, the power supply input pin VCC of the chip is separately connected to the logic control circuit 11, the high-voltage starting circuit 12, the high-side driver 13 and a low-side driver 14;
the pin HV as the input of the high-voltage starting circuit is connected to the high-voltage starting circuit 12, and the output end of the high-voltage starting circuit 12 are separately connected to the logic control circuit 11, the high-side driver 13 and the low-side driver 14;
the logic control circuit 11 is connected to the plurality of input/output I/O) ends, from I/O_1 to I/O_n shown in the figure;
a first control signal output end of the logic control circuit 11 is connected to a driving signal input end of the high-side driver 13, and a signal output end of the high-side driver 13 is connected to a gate of the first gallium nitride power transistor K1;
a second control signal output end of the logic control circuit 11 is connected to a driving signal input end of the low-side driver 14, and a signal output end of the low-side driver 14 is connected to a gate of the second gallium nitride power transistor K2; and
the high-voltage input positive pin V+ is connected to a drain of the first gallium nitride power transistor K1, and a source of the second gallium nitride power transistor K2 is connected to the high-voltage input negative pin V−; and a source of the first gallium nitride power transistor K1 is connected to a drain of the second gallium nitride power transistor K2 and is connected to the half-bridge output pin HB.

In addition, earthing terminals of the logic control circuit 11, the high-voltage starting circuit 12, the high-side driver 13 and the low-side driver 14 are further separately connected to the high-voltage input negative pin V−; and a feedback end of the high-side driver 13 is connected to the half-bridge output pin HB, and a feedback end of the low-side driver 14 is connected to the high-voltage input negative end V−.

The input/output I/O of the logic control circuit can be configured according to an application architecture of the half-bridge topology, and in a specific application, the input/output I/O) can be configured as a feedback signal input, a control signal input/output, a guard signal input/output and the like.

Therefore, in an actual application, a first control signal, which is PWMH, and a second control signal, which is PWML, can be outputted according to the input signals of the plurality of input/output I/O ends. In a specific application, the first control signal PWMH and the second control signal PWML are complementary pulse width modulation signals.

The high-side driver 13, according to the first control signal PWMH, outputs a first gate driving signal GTH of the first gallium nitride power transistor K1; the low-side driver 14, according to the second control signal PWML, outputs a second gate driving signal GTL of the second gallium nitride power transistor K2.

The high-side driver 13 and the low-side driver 14 each include a level shift circuit and a driving circuit. The first control signal PWMH enters the high-side driver 13 to generate a first gate driving signal GTH, and a potential difference between the first gate driving signal GTH and the half-bridge output pin HB controls turn-on and turn-off of the first gallium nitride power transistor K1; and the second control signal PWML enters the low-side driver 14 to generate a second gate driving signal GTL, and a potential difference between the second gate driving signal GTL and the high voltage input negative end V− controls turn-on and turn-off of the second gallium nitride power transistor K2. Under the condition that the first control signal PWMH and the second control signal PWML are the complementary pulse width modulation signals, the first gate driving signal GTH and the second gate driving signal GTL drive the first gallium nitride power transistor K1 and the second gallium nitride power transistor K2 to be alternately turned on and turned off. Because the first gallium nitride power transistor and the second gallium nitride power transistor are driven to be alternately turned on and turned off to generate the half-bridge driving signals VgH and VgL, and there is a dead time T_dt in the alternating process, FIG. 6 is a schematic diagram of the half-bridge driving signal provided by the present disclosure.

In the present disclosure, copper sheets are exposed to a back surface of the chip corresponding to the first base island region and the second base island region in physical implementation. During application, the back surface of the chip is welded to the PCB, which facilitates heat dissipation of the chip, and particularly improves heat dissipation of the driving control module 1, the first gallium nitride power transistor K 1 and the second gallium nitride power transistor K2.

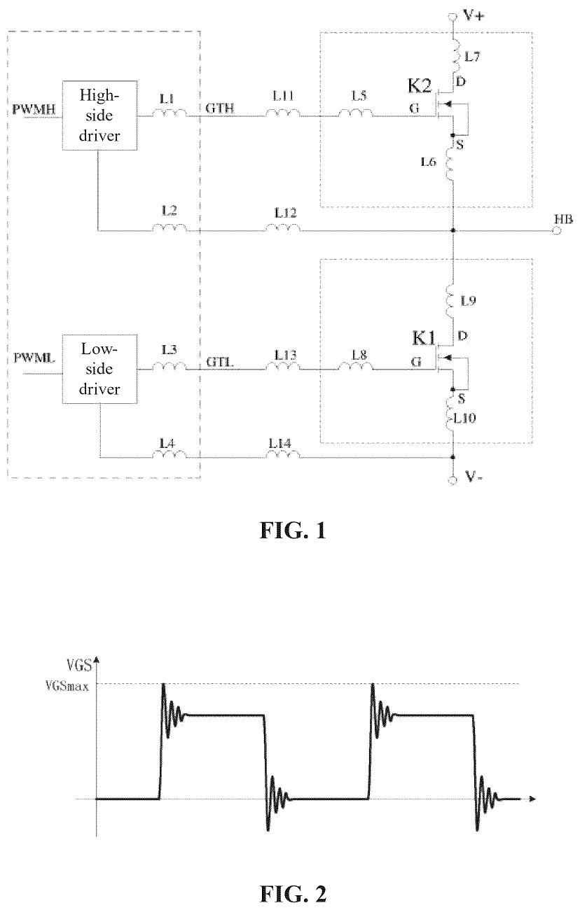

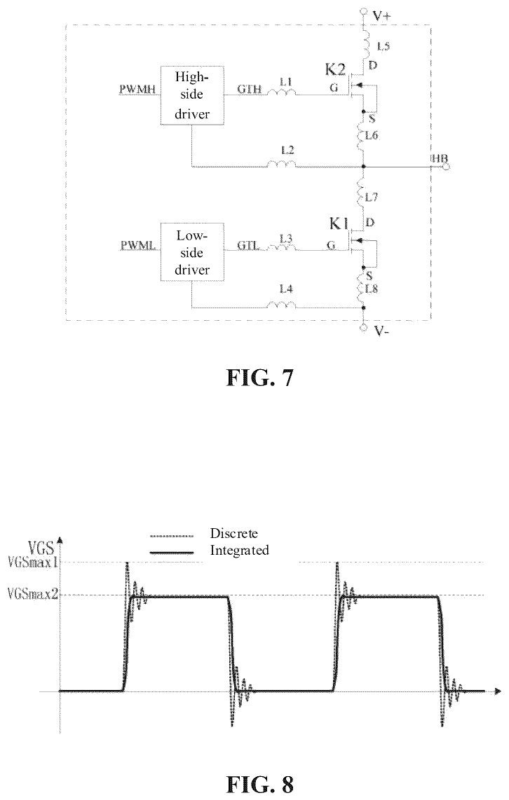

FIG. 7 is a schematic diagram of distribution of parasitic inductors in the half-bridge topology integrated chip for co-packaging a gallium nitride power device provided by the present disclosure. It can be seen that, compared with the discrete GaN power device and driving chip, the parasitic inductance is reduced greatly. Compared with FIG. 1, the number of the parasitic inductors of the driving loop decreases from 12 to 6 in the discrete GaN power device and driving chip.

FIG. 8 is a comparison diagram of a wave form in the present disclosure and the wave form of the Gate driving voltage VGS in FIG. 2. The dotted line is the Gate driving voltage VGS of the discrete GaN power device and driving chip, and the solid line is the Gate driving voltage VGS of the integrated chip. It can be seen from the figure that after the amount of the parasitic inductance is reduced, the ringing of the Gate driving voltage VGS nearly disappears, which effectively protects the power device.

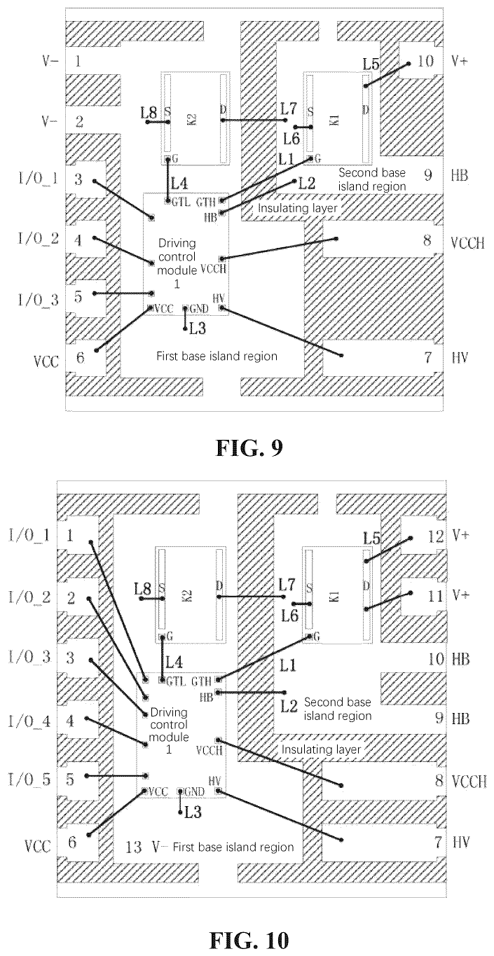

FIG. 9 shows a half-bridge driving chip structure applied to an LLC serial resonant architecture of a specific implementation of the half-bridge topology integration method provided by the present disclosure; and FIG. 10 shows a half-bridge driving chip structure applied to an active clamping flyback architecture of a specific implementation by using the half-bridge topology integration method provided by the present disclosure.

It can be known from the above two specific structures that based on the half-bridge topology integration method provided by the present disclosure, the specific frame type and size can be determined according to an application environment and system parameters. Positions of the pins and the number and definition of the I/O ports all can be decided according to an actual application demand. The above two are only examples of specific implementations, which are not intended to define the actual application implementations of the present disclosure.

According to the half-bridge topology integration method for co-packaging a gallium nitride power device and the chip provided by the embodiments of the present disclosure, aiming at the characteristics of the GaN power device, the high-voltage starting circuit of half-bridge topology, the logic control circuit, the dedicated driving circuit for the GaN power device and the GaN power device are packaged and integrated in the same chip. The driving circuit and the power device are directly connected by internal bonding, so that the bonding parasitic inductance is reduced. The parasitic inductance of the PCB is removed, and the parasitic inductance of the driving loop is reduced greatly, so that the GaN power device can be effectively prevented from being damaged. Moreover, a peripheral application is more concise due to a full integration technology, so that the size of the application product is reduced. Isolation is achieved by the insulating layer that separates the base island regions, the pin of the low-voltage signal is arranged on one side and the pin of the high-voltage signal is arranged on the other side with a packaging architecture, so that isolation of physical spaces of the high-voltage and low-voltage signals is guaranteed. The copper sheets are exposed to the back surfaces of the base island regions, so that the back surface can be directly welded to the PCB when the chip is applied, which guarantees the heat dissipation performance of the chip. Compared with the prior art, the parasitic parameters in the driving loop are reduced in the half-bridge topology integrated chip. The number of peripheral devices of a power supply chip is greatly reduced while heat dissipation of the power device is guaranteed, so that the power density is improved, the device is easy to debug, and the application cost is reduced.

Those skilled in the art can further realize that units and arithmetic steps in the examples described in the embodiments disclosed herein can be realized by way of electronic hardware, computer software or combination thereof. In order to describe interchangeability of hardware and software clearly, compositions and steps of the examples have been generally described in the description according to functions. Execution of these functions by way of hardware or software is dependent on a specific application and a design constraint condition of the technical scheme. Professionals can realize the described functions for each specific application by using different methods, and the implementation shall not be considered as exceeding the scope of the disclosure.

Steps of the method or algorithm described in combination with embodiments disclosed herein can be implemented by way of a software module executed by hardware and process or combination thereof. The software module can be disposed in a random-access memory (RAM), an internal memory, a read-only memory (ROM), an electrical programmable ROM, an electrical erasable programmable ROM, a register, a hard disc, a movable disc, a CD-ROM or any other forms of storage media known in the technical field.

The purposes, technical solutions and beneficial effects of the present disclosure are described in further detail with reference to the above-mentioned specific embodiments. The above embodiments are merely the preferred ones of the present disclosure and are not used to define the scope of protection of the present disclosure. Any modification, equivalent replacement, improvement, etc. made within the spirit and principle of the present disclosure shall be regarded as within the protection scope of the present disclosure.

1. A half-bridge topology integration method for co-packaging a gallium nitride power device, the method comprising:
packaging a driving control module, a first gallium nitride power transistor and a second gallium nitride power transistor in a chip to form a co-packaged gallium nitride half-bridge topology integrated chip, wherein the driving control module comprises a logic control circuit and a half-bridge driving circuit; the half-bridge driving circuit comprises a high-voltage starting circuit, a high-side driver and a low-side driver;
isolating a first base island region and a second base island region with an insulating layer in the chip;
arranging the driving control module and the second gallium nitride power transistor in the first base island region, and arranging the first gallium nitride power transistor in the second base island region; and
connecting the logic control circuit to the half-bridge driving circuit, connecting the first gallium nitride power transistor and the second gallium nitride power transistor in series, and separately connecting a driving output of the half-bridge driving circuit to driving ends of the first gallium nitride power transistor and the second gallium nitride power transistor, wherein the half-bridge driving circuit drives, according to a control signal output by the logic control circuit, the first gallium nitride power transistor and the second gallium nitride power transistor to be alternately turned on and turned off.

2. The method of claim 1, wherein a package uses a power quad dual flat pin-free packaging structure, which is a PDNE package, and the method further comprises:
arranging a pin connected to a high-voltage signal in the chip on one side of the PDNF package, and arranging a pin connected to a low-voltage signal in the chip on an other side of the PDNF package;
wherein pins pins connected to the high-voltage signal comprises pin V+, which is a high-voltage input positive, VCCH pin as a power supply input of the high-side driver, pin HV as an input of the high-voltage starting circuit and a half-bridge output pin HB; the pins connected to the low-voltage signal comprises pin VCC, which is a power supply input of the chip and a plurality of input/output I/O; and
pins of the chip further comprise a high-voltage input negative pin V−, wherein the high-voltage input negative pin V− is arranged on the other side of the PDNF package or a third side.

3. The method of claim 2, wherein the pin VCC as the power supply input of the chip is separately connected to the logic control circuit, the high-voltage starting circuit, the high-side driver and the low-side driver;
the pin HV as the input of the high-voltage starting circuit is connected to the high-voltage starting circuit, and an output end of the high-voltage starting circuit is separately connected to the logic control circuit, the high-side driver and the low-side driver;
the logic control circuit is connected to the plurality of input/output I/O;
a first control signal output end of the logic control circuit is connected to a driving signal input end of the high-side driver, and a signal output end of the high-side driver is connected to a gate of the first gallium nitride power transistor;
a second control signal output end of the logic control circuit is connected to a driving signal input end of the low-side driver, and a signal output end of the low-side driver is connected to a gate of the second gallium nitride power transistor; and
a high-voltage input positive pin V+ is connected to a drain of the first gallium nitride power transistor, and a source of the second gallium nitride power transistor is connected to the high-voltage input negative pin V−; and
a source of the first gallium nitride power transistor is connected to a drain of the second gallium nitride power transistor and is connected to the half-bridge output pin HB.

4. The method of claim 2, wherein the logic control circuit, according to input signals of the plurality of input/output I/O, outputs a first control signal, which is PWMH, and a second control signal, which is PWML;
the high-side driver, according to the first control signal, which is PWMH, outputs a first gate driving signal of the first gallium nitride power transistor; the low-side driver, according to the second control signal, which is PWML, outputs a second gate driving signal of the second gallium nitride power transistor; and the first gallium nitride power transistor and the second gallium nitride power transistor, driven by the first gate driving signal and the second gate driving signal, are alternately turned on and turned off; and
wherein the first control signal and the second control signal are complementary pulse width modulation signals.

5. The method of claim 1, wherein the method further comprises:
further connecting earthing terminals of the logic control circuit, the high-voltage starting circuit, the high-side driver and the low-side driver to a high-voltage input negative pin V−; and
connecting a feedback end of the high-side driver to a half-bridge output pin HB.

6. The method of claim 1, wherein pins of the chip are isolated by the insulating layer.

7. The method of claim 1, wherein copper sheets are exposed to a back surface of the chip corresponding to the first base island region and the second base island region.

8. The method of claim 1, wherein a package is specifically a DNF8*8 package.

9. A half-bridge topology integrated chip obtained by the half-bridge topology integration method for co-packaging a gallium nitride power device of claim 1.
